(19) United States
(12) Patent Application Publication
(10) Pub. No.: US 2002/0177049 A1
(43) Pub. Date: Nov. 28, 2002

(54) Phase-shifting mask and method of fabricating the same

(75) Inventor: Haruo Iwasaki, Tokyo (JP)

Correspondence Address: Norman P. Soloway, HAYES SOLOWAY P.C., 130 W. Cushing Street, Tucson, AR, 85701, US

(73) Assignee: NEC CORPORATION

(21) Appl. No.: 10/152,268

(22) Filed: May 21, 2002

(30) Foreign Application Priority Data
May 22, 2001 (JP) 2001-152611

(51) Int. Cl. G03F 9/00; G03C 5/00

(52) U.S. Cl. 430/5; 430/322; 430/323

(57) ABSTRACT

A phase-shifting mask includes (a) a substrate, (b) a light-shielding film formed on the substrate and having a plurality of first openings and a plurality of second openings, and (c) a phase-shifter formed on the substrate only in the first opening of the light-shielding film.

### BACKGROUND OF THE INVENTION

1. Field of the Invention

The invention relates to a phase-shifting mask and a method of fabricating the same.

2. Description of the Related Art

A phase-shifting mask used as a photo-mask in a process of fabricating a semiconductor integrated circuit is comprised generally of a light-shielding film having a plurality of openings, and a phase-shifter which shifts phases of lights passing through openings located adjacent to each other such that the phases are different from each other by 180 degrees. The phase-shifter prevents lights passing through openings located adjacent to each other from interfering with each other, and further from the lights being multiplexed with respect to intensity.

FIG. 1A is a perspective view of a conventional phase-shifting mask, and FIG. 1B is a top plan view of the conventional phase-shifting mask illustrated in FIG. 1A.

With reference to FIGS. 1A and 1B, the illustrated conventional phase-shifting mask is comprised of a glass substrate 10, and a light-shielding film 11 formed on the glass substrate 10 and composed of chromium (Cr). The light-shielding film 11 is formed with a plurality of first openings 12 and a plurality of second openings 13. The glass substrate 10 is formed below the first openings 12 with recesses 25 each defining a phase-shifter, but is not formed below the second openings 13 with such recesses 25 as defining a phase-shifter.

FIGS. 2A to 2G are cross-sectional views of the phase-shifting mask illustrated in FIGS. 1A and 1B, illustrating respective steps of a method of fabricating the same. Hereinbelow is explained a method of fabricating the conventional phase-shifting mask illustrated in FIGS. 1A and 1B, with reference to FIGS. 2A to 2G.

First, as illustrated in FIG. 2A, the light-shielding film 11 composed of chromium is formed on the glass substrate 10. When a KrF light source is to be used as a light source, the light-shielding film 11 is designed to have a thickness of about 110 nm.

Then, as illustrated in FIG. 213, a photoresist 14 is coated over the light-shielding film 11, and is patterned by means of a mask painter (not illustrated).

Then, as illustrated in FIG. 2C, the light-shielding film 11 is dry-etched by a mixture gas of Cl₂ and O₂ with the patterned resist 14 being used as a mask, to thereby form the light-shielding film 11 with the first openings 12 and the second openings 13. Thereafter, the photoresist 14 is removed.

Then, as illustrated in FIG. 2D, a photoresist 15 is coated over the light-shielding film 11 and exposed portions of the glass substrate 10. Then, portions of the photoresist 15 below which the racesses 25 as a phase-shifter are to be formed through the first openings 12 are exposed to a light to thereby pattern the photoresist 15.

Then, as illustrated in FIG. 2E, the glass substrate 10 is dry-etched by a mixture gas of CF₄ and O₂ with both of the patterned photoresist 15 and the light-shielding film 11 being used as a mask. As a result, the glass substrate 10 is formed below the first opening 12 with a recess 10a.

Then, as illustrated in FIG. 2F, the recess boa is wet-etched at a sidewall thereof by HF etchant with both of the patterned photoresist 15 and the light-shielding film 11 being used as a mask. Boy being wet-etched, the recess 10a expands laterally with the result that the recess 25 defining a phase-shifter is formed below the first opening 12.

Finally, as illustrated in FIG. 2G, the photoresist 15 is removed. Thus, the phase-shifting mask as illustrated in FIGS. 1A and 1B is completed.

FIG. 3A is a perspective view of another conventional phase-shifting mask, and FIG. 3B is a top plan view of the conventional phase-shifting mask illustrated in FIG. 5A. The illustrated phase-shifting mask has a dual-trench structure.

With reference to FIGS. 3A and 3B, the illustrated conventional phase-shifting mask is comprised of a glass substrate 10, and a light-shielding film 11 formed on the glass substrate 10 and composed of chromium (Cr), similarly to the phase-shifting mask illustrated in FIGS. 1A and 1B. The light-shielding film 11 is formed with a plurality of first openings 12 and a plurality of second openings 13. The glass substrate 10 is formed below the first openings 12 with first recesses 21a and below the second openings 13 with second recesses 21b.

The first recesses 21a are deeper than the second recesses 21b. Accordingly, portions of the first recesses 21a deeper than the second recesses 21b act as a phase-shifter. In other words, the first recesses 12 formed below the first openings 12 can act as a phase-shifter, but the second recesses 13 formed below the second openings 13 cannot act as a phase-shifter.

FIGS. 4A to 4G ate cross-sectional views of the phase-shifting mask illustrated in FIGS. 5A and 5B, illustrating respective steps of a method of fabricating the same. Hereinbelow is explained a method of fabricating the conventional phase-shifting mask illustrated in FIGS. 3A and 3B, with reference to FIGS. 4A to 4G.

First, as illustrated in FIG. 4A, the light-shielding film 11 composed of chromium is formed on the glass substrate 10. When a KrF light source is to be used as a light source, the light-shielding film 11 is designed to have a thickness of about 110 nm.

Then, as illustrated in FIG. 413, a photoresist 14 is coated over the light-shielding film 11, and is patterned by means of a mask painter (not illustrated).

Then, as illustrated in FIG. 4C, the light-shielding film 11 is dry-etched by a mixture gas of Cl₂ and O₂ with the patterned resist 14 being used as a mask, to thereby form the light-shielding film 11 with the first openings 12 and the second openings 13. Thereafter, the photoresist 14 is removed.

Then, as illustrated in FIG. 4D, a photoresist 15 is coated over the light-shielding film 11 and exposed portions of the glass substrate 10. Then, portions of the photoresist 15 below which the first recesses 21a as a phase-shifter are to be formed through the first openings 12 are exposed to a light to thereby pattern the photoresist 15.

Then, as illustrated in FIG. 4E, the glass substrate 10 is dry-etched by a mixture gas of CF₄ and O₂ with both of the patterned photoresist 15 and the light-shielding film 11 being used as a mask. As a result, the glass substrate 10 is formed below the first opening 12 with a recess 10b. Thereafter, the photoresist 15 is removed.

Then, as illustrated in FIG. 4F, the glass substrate 10 is dry-etched by a mixture gas of CF₄ and O₂ with the light-shielding film 11 being used as a mask.

By dry-etching the glass substrate 10, the first recesses 21a are formed below the first openings 12, and the second recesses 21b are formed below the second openings 13, as illustrated in FIG. 4G. The first recesses 21a are deeper than the second recesses 21b, and hence, act as a phase-shifter. Thus, the phase-shifting mask as illustrated in FIGS. 3A and 3B is completed.

In the above-mentioned conventional phase-shifting masks illustrated in FIGS. 1A and 1B, and FIGS. 3A and 3B, a phase shifter is formed by forming a recess at a surface of the glass substrate 10 below the first openings 12 of the light-shielding film 11. In order to form such a recess in the conventional phase, shifting masks illustrated in FIGS. 1A and 1B, and FIGS. 3A and 33, the dry-etching processes are carried out, as illustrated in FIGS. 2E, 4E and 4F.

When a substrate is dry-etched, uniformity in a depth of a resultant recess is 5 nm (equivalence in retardation is 8.6 degrees), and accuracy in matching phases is 7 nm (equivalence in retardation is 5 degrees). Uniformity in a depth of a recess and accuracy in matching phases both of which are required to a phase-shifting mask are both 2.5±2 degrees. This means that dry-etching process cannot guarantee the required uniformity and accuracy.

Japanese Unexamined Patent Publication No. 6-180497 (A) has suggested a method of fabricating a phase-shifting mask, including the step of partially removing a film composed of silicon dioxide (SiO₂) A non-removed portion of the SiO₂ film defines a phase-shifting mask. Specifically, the method includes the steps of dry-etching the film by an intermediate thickness thereof, and wet-etching the SiO₂ film by the rest of the thickness thereof. Hence, a resultant phase-shifting mask is composed of SiO₂.

However, it is difficult to dry-etch the SiO₂ film by an intermediate thickness thereof. In addition, two etching steps have to be carried out in the method. As a result, it would be impossible to fabricate a phase-shifting mask with ease.

Japanese Unexamined Patent Publication No. 5-289306 has suggested a phase-shifting mask including a substrate, a light-shielding film formed on the substrate, a phase-shifting pattern formed on the light-shielding mask and containing silicon oxide, characterized by a film formed on the substrate which film is composed of MgF_{2-2X}O_{y}, CaF_{2-2X}O_{y}, LiF_{2-2X}O_{y}, BaF_{2-2X}O_{y}, La₂F_{6-2X}O_{y}, or Ce₂F_{6-2X}O_{y}.

Japanese Unexamined Patent Publication No. 7-159971 (A) has suggested an optical mask including a transparent substrate, an etching stopper layer, a phase-shifting layer, and a light-shielding layer formed on the transparent substrate in this order. The phase-shifting layer is composed of SiO₂ or SiO alone or in combination. A wavelength λ of a light to which the mask is exposed, a thickness D of the phase-shifting layer, and an index of refraction N of the material of which the phase-shifting layer is composed satisfy the following equations (A) and (B).

D=mλ/2N(m is a positive integer) (A)

D=λ/[2(n−1)] (B)

Japanese Unexamined Patent Publication No. 7-248610 (A) has suggested a phase-inverting mask including a transparent substrate formed with a plurality of trenches spaced away from adjacent ones by a certain distance, an opaque layer partially buried in the trench and a phase-inverting layer formed on the transparent substrate between the trenches.

Japanese Unexamined Patent Publication No. 10-104817 (A) has suggested a phase-shifting mask including a transparent substrate, a phase-shifting layer formed directly on the transparent substrate, and a patterned light-shielding film formed on the phase-shifting layer.

However, the phase-shifting masks suggested in the above-mentioned Publications are accompanied with a problem that accuracy in matching phases cannot satisfy the required accuracy.

### SUMMARY OF THE INVENTION

In view of the above-mentioned problems in the conventional phase-shifting masks, it is an object of the present invention to provide a phase-shifting mask which is capable of accomplishing high accuracy in matching phases and being fabricated with ease.

It is also an object of the present invention to provide a method of fabricating such a phase-shifting mask as mentioned above.

In one aspect of the present invention, there is provided a phase-shifting mask including (a) a substrate, (b) a light-shielding film formed on the substrate and having at least one first opening and at least one second opening, and (c) a phase-shifter formed on the substrate only in the first opening of the light-shielding film.

For instance, the phase-shifter is comprised preferably of a silicon dioxide (SiO₂) film.

It is preferable that the silicon dioxide film has a thickness equal to or smaller than a thickness of the light-shielding film, in which case, the silicon dioxide film may have a thickness in the range of about 200 nm to about 250 nm.

There is further provided a phase-shifting mask including (a) a substrate, (b) a light-shielding film formed on the substrate and having at least one opening, and (c) a phase-shifter formed on the substrate in the opening of the light-shielding film.

In another aspect of the present invention, there is provided a method of fabricating a phase-shifting mask, including the steps of (a) forming a light-shielding film on a substrate such that the light-shielding film has at least one first opening and at least one second opening, and (b) forming a phase-shifter on the substrate only in the first opening of the light-shielding film.

For instance, the step (b) includes the steps of (b1) depositing silicon dioxide over the light-shielding film, and (b2):removing the silicon dioxide in an area other than the first opening.

It is preferable that the silicon dioxide is removed in the step (b2) such that a remaining silicon dioxide film has a thickness equal to or smaller than a be thickness of the light-shielding film.

It is preferable that the silicon dioxide is removed in the step (b2) such that a remaining silicon dioxide film has a thickness in the range of about 200 nm to about 250 nm.

It is preferable that etching for forming the phase-shifter in the step (b) is wet etching.

There is further provided a method of fabricating a phase-shifting mask, including the steps of (a) forming a light-shielding film on a substrate such that the light-shielding film has at least one opening, and (b) forming a phase-shifter on the substrate in the opening of the light-shielding film.

There is still further provided a method of fabricating a phase-shifting mask, including the steps of (a) forming a light-shielding film on a substrate such that the light-shielding film has at least one first opening and at least one second opening, (b) depositing silicon dioxide over the light-shielding film, (c) wet-etching the silicon dioxide for removal until the light-shielding film is exposed, and (d) wet-etching the silicon dioxide for removal out of the second opening.

There is yet further provided a method of fabricating a phase-shifting mask, including the steps of (a) forming a light-shielding film on a substrate such that the light-shielding film has at least one opening, (b) depositing silicon dioxide over the light-shielding film, (c) wet-etching the silicon dioxide for removal until the light-shielding film is exposed, and (d) wet-etching the silicon dioxide for removal out of the opening.

The advantages obtained by the aforementioned present invention will be described hereinbelow.

In the present invention, the phase-shifter is formed on a substrate in being buried in an opening of a light-shielding film.

In contrast, the conventional phase-shifter is formed as a recess at a surface of a substrate below an opening of a light-shielding film. Such a recess is formed by dry etching. The phase-shifter suggested in Japanese Unexamined Patent Publication No. 6-180497 is formed by dry-etching and then wet-etching a SiO₂ film.

In accordance with the present invention, the phase-shifter can be fabricated on a substrate below an opening of a light-shielding film without carrying out dry-etching for forming a recess at a surface of the substrate. In addition, the phase-shifter in accordance with the present invention can be fabricated without carrying out both dry-etching and wet-etching for partially removing a silicon dioxide film.

Thus, the present invention present s a phase-shifting mask which can be readily fabricated and has high accuracy.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1A is A perspective view of a conventional phase-shifting mask.

FIG. 1B is a top plan view of the conventional phase-shifting mask illustrated in FIG. 1A.

FIGS. 2A to 2G are cross-sectional views of the phase-shifting mask illustrated in FIGS. 1A and 1B, illustrating respective steps of a method of fabricating the same.

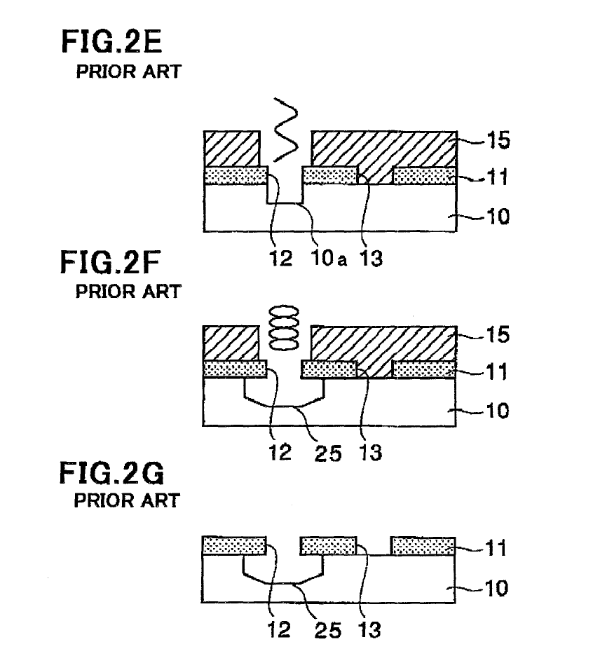

FIG. 3A is a perspective view of another conventional phase-shifting mask.

FIG. 3B is a top plan view of the conventional phase-shifting mask illustrated in FIG. 3A.

FIGS. 4A to 4G are cross-sectional views of the phase-shifting mask illustrated in FIGS. 3A and 3B, illustrating respective steps of a method of fabricating the same.

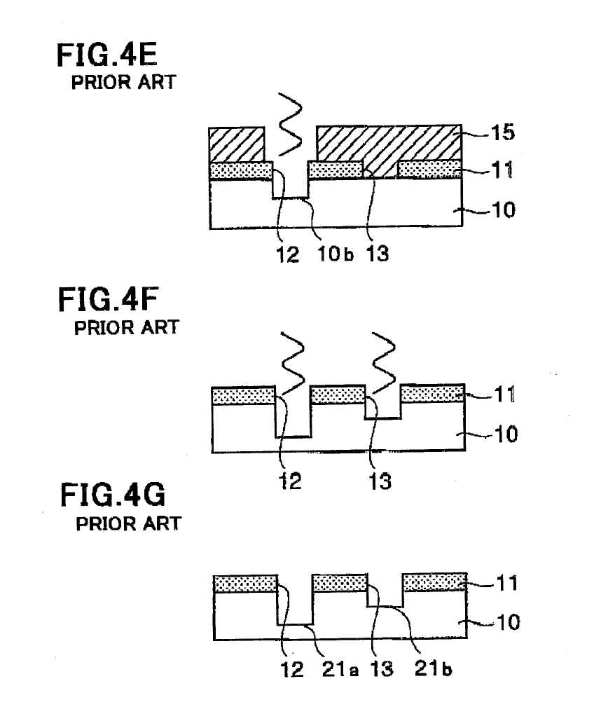

FIG. 5A is a perspective view of a phase-shifting mask in accordance with a preferred embodiment of the present invention.

FIG. 5B is a top plan view of the phase-shifting mask illustrated in FIG. 5A.

FIGS. 6A to 6J are cross-sectional views of the phase-shifting mask illustrated in FIGS. 5A and 5E, illustrating respective steps of a method of fabricating the same.

### DESCRIPTION OF THE PREFERRED EMBODIMENT

A preferred embodiment in accordance with the present invention will be explained hereinbelow with reference to drawings.

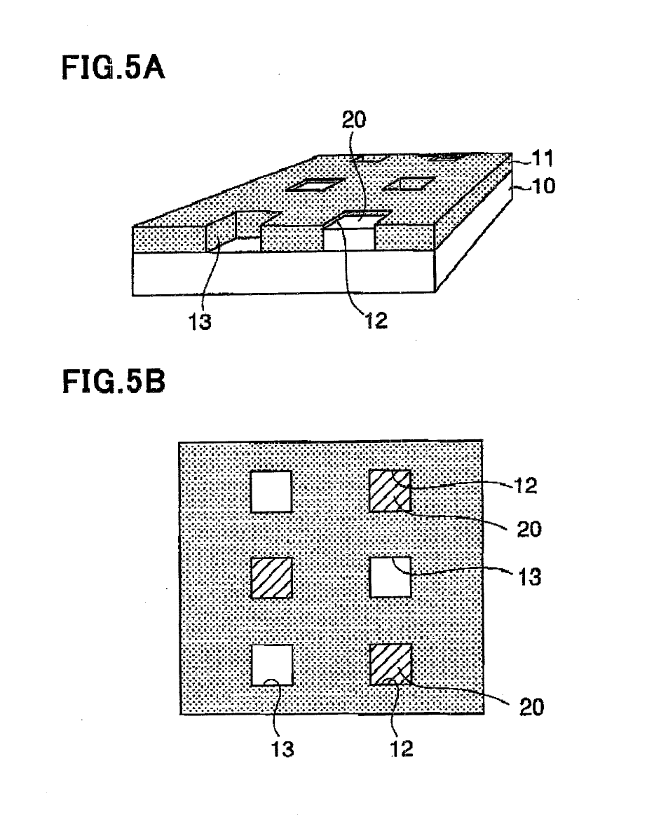

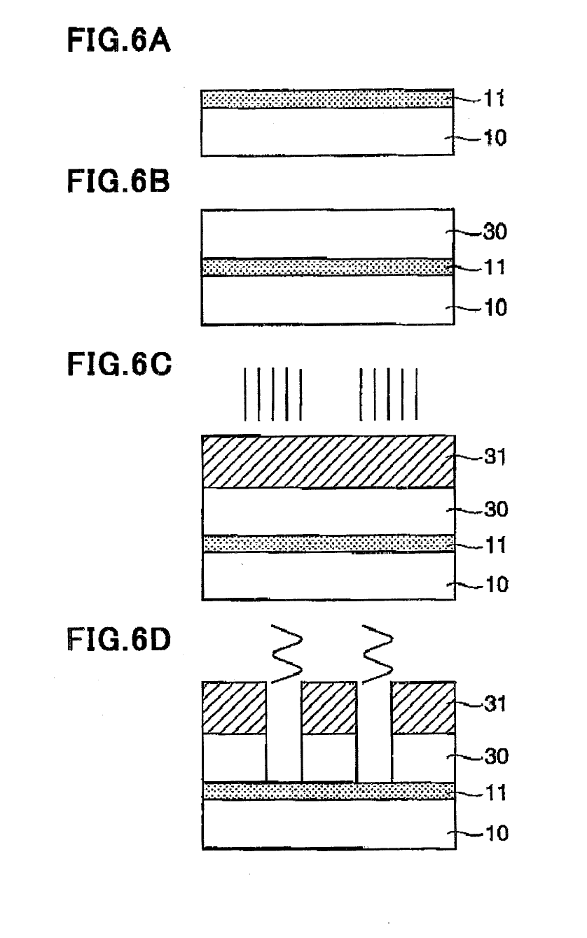

FIG 5A is a perspective view of a phase-shifting mask in accordance with a preferred embodiment of the present invention, and FIG. 5B is a top plan view of The phase-shifting mask illustrated in FIG. 5A.

With reference to FIGS. 5A and 5B, a phase-shifting mask in accordance with the embodiment is comprised of a transparent substrate such as a glass substrate 10, a light-shielding film 11 formed on the glass substrate 10 and composed of chromium (Cr), and phase-shifters 20 composed of a silicon dioxide (SiO₂) film.

The light-shielding film 11 is formed with a plurality of first openings 12 and a plurality of second openings 13. The phase-shifters 20 composed of a silicon dioxide film is formed on the glass substrate 10 in the first openings 12 of the light-shielding film II. It should be noted that the phase-shifters 20 are formed only in the first openings 12, but not formed in the second openings 13.

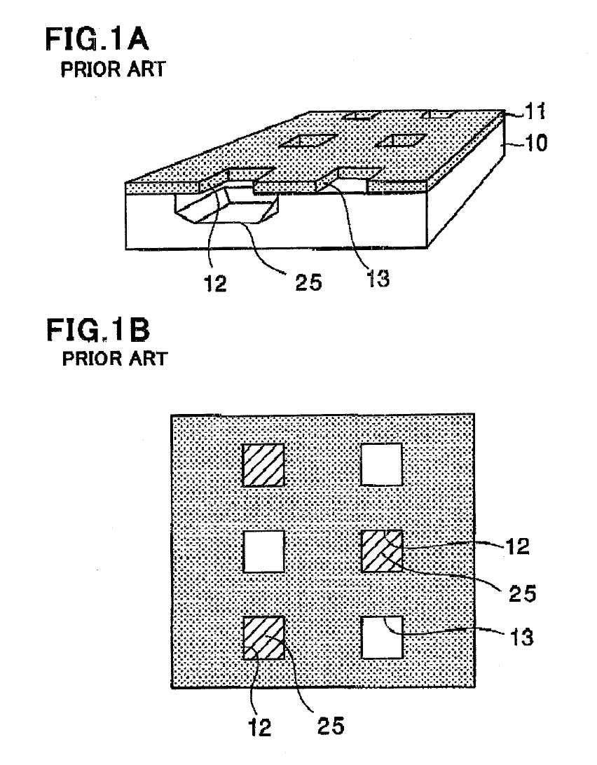

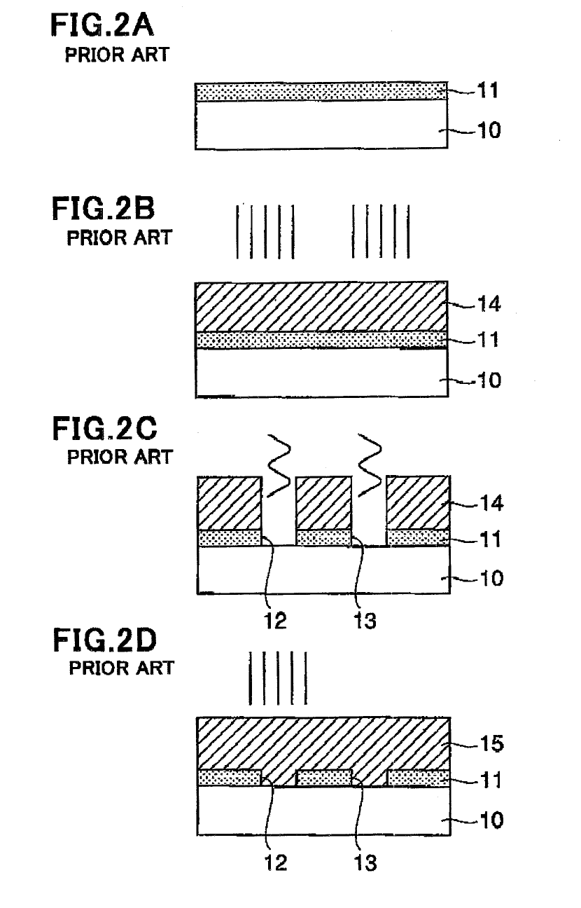

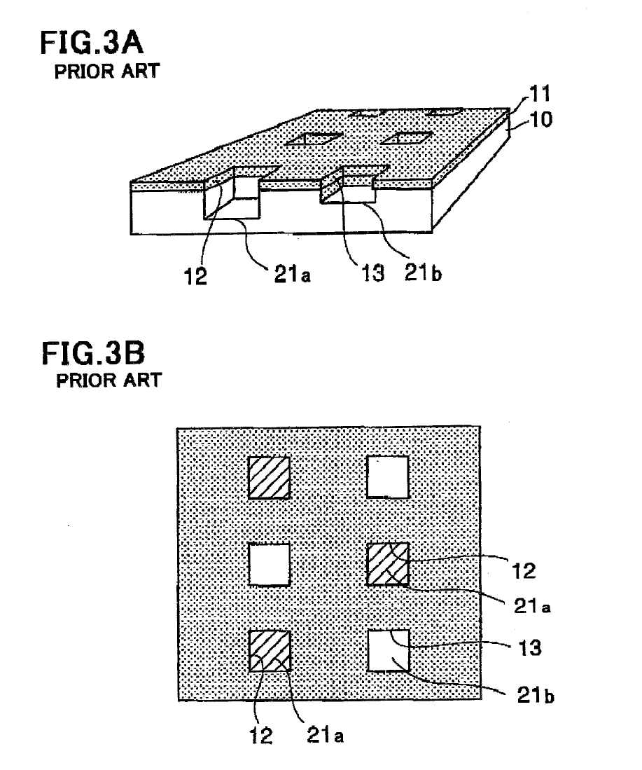

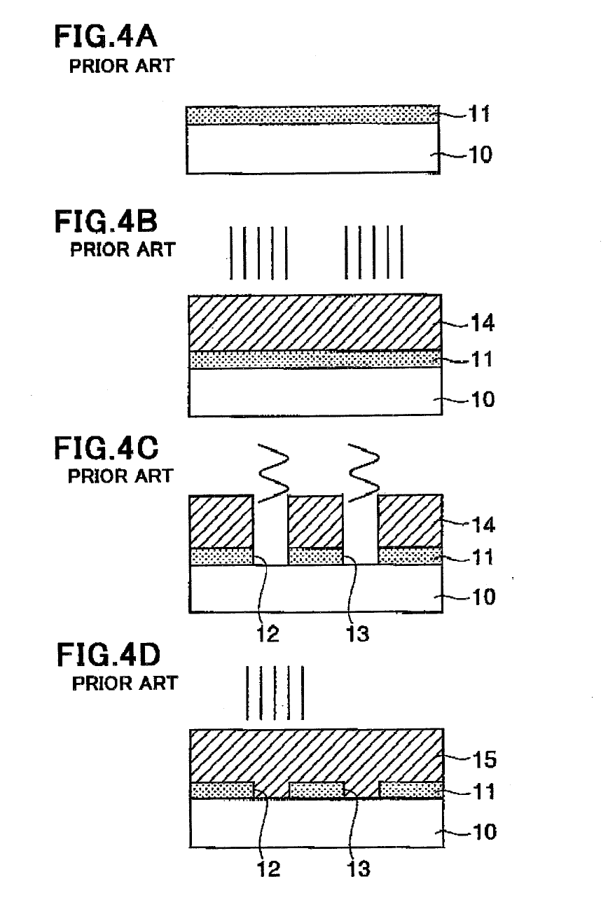

In the above-mentioned conventional phase-shifting masks illustrated in FIGS. 1A and 1B, and FIGS. 3A and 3B, the phase-shifter 25 is formed as a recess by dry-etching at a surface of the glass substrate 10 below the openings 12 of the light-shielding film 11.

In contrast, the phase-shifter 20 in the embodiment can be formed on the glass substrate 10 in the first openings 12 of the light-shielding film without carrying out dry-etching for forming a recess at a surface of the glass substrate 10.

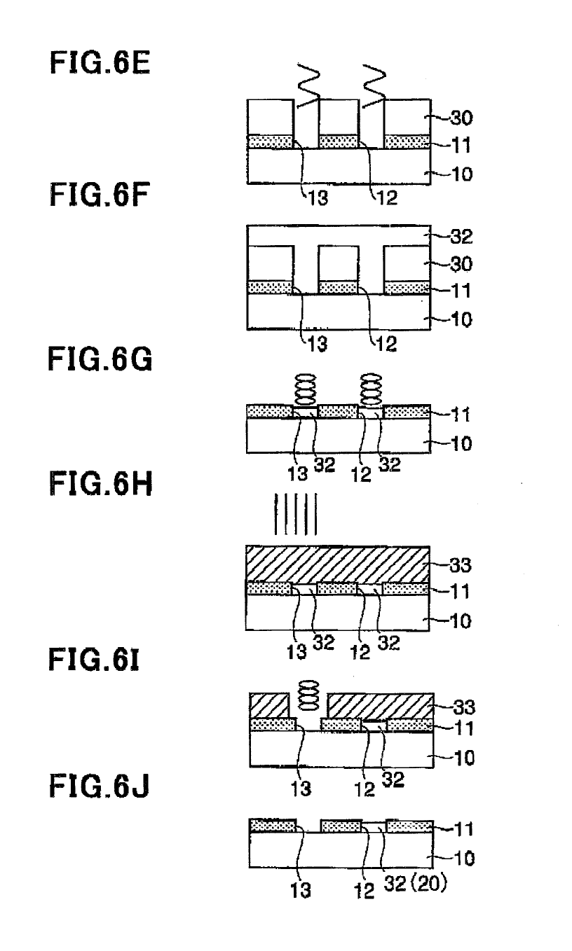

FIGS. 6A to 6J are cross-sectional views of the phase-shifting mask in accordance with the embodiment, illustrating respective steps of a method of fabricating the same. Hereinbelow is explained a method of fabricating the phase-shifting mask in accordance with the embodiment, with reference to FIGS. 6A to 6J.

First, as illustrated in FIG. 6A, the light-shielding film 11 composed of chromium is formed on the glass substrate 10. When a KrF light source is to be used as a light source, the light-shielding film 11 is designed to have a thickness in the range of 250 nm to 350 nm. This is because that the phase-shifter 20 comprised of a silicon dioxide film has a thickness in the range of about 200 nm to about 250 nm, and the light-shielding film 11 has to have a thickness sufficient to bury the phase-shifter 20 therein.

Then, as illustrated in FIG. 6B, a silicon dioxide film 30 is formed entirely over the light-shielding film 11. Since the light-shielding film 11 is thick, it is impossible to dry-etch the light-shielding film 11 by ordinary photolithography in which a patterned photoresist is used as a mask. Hence, the light-shielding film 11 is etched with the silicon dioxide film 30 being used as a mask.

Then, as illustrated in FIG. 6C, a photoresist 31 is coated over the silicon dioxide film 30, and is patterned by means of a mask painter (not at illustrated).

Then, as illustrated in FIG. 6D, the silicon dioxide film 30 is dry-etched by a mixture gas of CF₄ and O₂ with the patterned photoresist 31 being used as a mask. Thereafter, the photoresist 31 is removed.

Then, as illustrated in FIG. 6E, the light-shielding film 11 is dry-etched by a mixture gas of Cl₂ and O₂ with the patterned silicon dioxide film 30 being used as a mask. As a result, the light-shielding film 11 is formed with the first openings 12 and the second openings 13.

Then, as illustrated in FIG. 6F, a silicon dioxide film 32 is deposited entirely over the silicon dioxide film 30 and exposed portions of the glass substrate 10.

Then, as illustrated in FIG. 6G, the silicon dioxide films 32 and 30 are etched until the light-Shielding film 11 appears.

Then, as illustrated in FIG. 6H, a photoresist 33 is coated over the light-shielding film 11 and the silicon dioxide film 32. Then, the photoresist 33 is patterned by photolithography and dry etching such that the silicon dioxide film 32 deposited in the second openings 13 is exposed.

Then, as illustrated in FIG. 61, he silicon dioxide film 32 deposited in the second openings 13 is removed by wet-etching through the use of HP etchant with the patterned photoresist 33 being used as a mask.

Then, as illustrated in FIG. 6J, the photoresist 33 is removed. Thus, there is completed the phase-shifter mask in which the silicon dioxide film 32 defines the phase-shifter 20 in the first openings 12.

Retardation is controlled by controlling a depth of a recess to be formed at a surface of a glass substrate. When a glass substrate is wet-etched, uniformity in a depth of a resultant recess is 2.5 nm (equivalence in retardation is 1.8 degrees), and accuracy in matching phases is 3.5 nm (equivalence in retardation is 2.5 degrees). Uniformity in a depth of a recess and accuracy in matching phases both of which are required to a phase-shifting mask are both 2.5±2 degrees This means that wet-etching process and hence the phase-shifting mask in accordance with the embodiment can guarantee the required uniformity and accuracy.

In accordance with the above-mentioned embodiment, the phase-shifter 20 can be fabricated only by wet-etching. Accordingly, the phase-shifting mask in accordance with the embodiment can satisfy the required uniformity and accuracy.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2001-152611 filed on May 22, 2001 including specification, claims, drawings and summary is incorporated herein by reference in its entirety.

What is claimed is:

1. A phase-shifting mask comprising:
(a) a substrate;
(b) a light-shielding film formed on said substrate and having at least one first opening and at least one second opening; and
(c) a phase-shifter formed on said substrate only in said first opening of said light-shielding film.

2. The phase-shifter as set forth in claim 1, wherein said phase-shifter is comprised of a silicon dioxide (SiO₂) film.

3. The phase-shifter as set forth in claim 2, wherein said silicon dioxide film has a thickness equal to or smaller than a thickness of said light-shielding film.

4. The phase-shifter as set forth in claim 3, wherein said silicon dioxide film has a thickness in the range of about 200 nm to about 250 nm.

5. A phase-shifting mask comprising:
(a) a substrate;
(b) a light-shielding film formed on said substrate and having at least one opening; and
(c) a phase-shifter formed on said substrate in said opening of said light-shielding film.

6. The phase-shifter as set forth in claim 5, wherein said phase-shifter is comprised of a silicon dioxide (SiO₂) film.

7. The phase-shifter as set forth in claim 6, wherein said silicon dioxide film has a thickness equal to or smaller than a thickness of said light-shielding film.

8. The phase-shifter as set forth in claim 7, wherein said silicon dioxide film has a thickness in the range of about 200 nm to about 2.50 nm.

9. A method of fabricating a phase-shifting mask, comprising the steps of:
(a) forming a light-shielding film on a substrate such that said light-shielding film has at least one first opening and at least one second opening, and
(b) forming a phase-shifter on said substrate only in said first opening of said light-shielding film.

10. The method as set forth in claim 9, wherein said step (b) includes the steps of:
(b1) depositing silicon dioxide over said light-shielding film; and
(b2) removing said silicon dioxide in an area other than said first opening.

11. The method as set forth in claim 10, wherein said silicon dioxide is removed in said step (b2) such that a remaining silicon dioxide film has a thickness equal to or smaller than a thickness of said light-shielding film.

12. The method as set forth in claim 11, wherein said silicon dioxide is removed in said step (b2) such that a remaining silicon dioxide film has a thickness in the range of about 200 nm to about 250 nm.

13. The method as set forth in claim 9, wherein etching for forming said phase-shifter in said step (b) is wet etching.

14. A method of fabricating a phase-shifting mask, comprising the steps of:
(a) forming a light-shielding film on a substrate such that said light-shielding film has at least one opening; and
(b) forming a phase-shifter on said substrate in said opening of said light. shielding film.

15. The method as set forth in claim 14, wherein said step (b) includes the steps of:
(b1) depositing silicon dioxide over said light-shielding film; and
(b2) removing said silicon dioxide in an area other than said opening.

16. The method as set forth in claim 15, wherein said silicon dioxide is removed in said step (b2) such that a remaining silicon dioxide film has a thickness equal to or smaller than a thickness of said light-shielding film.

17. The method as set forth in claim 16, wherein said silicon dioxide is removed in said step (b2) such that a remaining silicon dioxide film has a thickness in the range of about 200 nm to about 250 nm.

18. The method as set forth in claim 14, wherein etching for forming said phase-shifter in said step (b) is wet etching.

19. A method of fabricating a phase-shifting mask, comprising the steps of:
(a) forming a light-shielding film on a substrate such that said light-shielding film has at least one first opening and at least one second opening;
(b) depositing silicon dioxide over said light-shielding film;,
(c) wet-etching said silicon dioxide for removal until said light-shielding film is exposed; and
(d) wet-etching said silicon dioxide for removal out of said second opening.

20. A method of fabricating a phase-shifting mask, comprising the steps of:
(a) forming a light-shielding film on a substrate such that said light-shielding film has at least one opening;
(b) depositing silicon dioxide over said light-shielding film;
(c) wet-etching said silicon dioxide for removal until said light-shielding film is exposed; and
(d) wet-etching said silicon dioxide for removal out of said opening.
